(19) United States
(12) Patent Application Publication
(10) Pub. No.: US 2025/0377390 A1
(43) Pub. Date: Dec. 11, 2025

(54) CURRENT ESTIMATION OR SENSING METHODS

(71) Applicant: STMicroelectronics International N.V., Geneva (CH)

(72) Inventors: Vanni POLETTO, Milano (IT); Simone BIANCHI, Alessandria (IT); Matteo SIGNINI, Pavia (IT); Marco BRERA, Milano (IT); Antoine PAVLIN, Puyricard (FR)

(73) Assignee: STMicroelectronics International N.V., Geneva (CH)

(21) Appl. No.: 19/225,443

(22) Filed: Jun. 2, 2025

(30) Foreign Application Priority Data
Jun. 6, 2024 (IT) 102024000012970

(51) Int. Cl. G01R 19/25; G01R 19/10; H02M 1/00; H02M 3/158

(52) U.S. Cl. CPC G01R 19/25; G01R 19/10; H02M 1/0009; H02M 3/158

(57) ABSTRACT

A high-side switch has a current flow path between a high-side reference and a switching node, and a low-side switch has a current flow path between the switching node and a low-side reference. The high-side switch is conductive during a first time interval and the low-side switch is conductive during a second time interval. An inductive element is coupled between the switching node and an output node. A switching voltage is sensed and filtered to provide a filtered voltage indicative of an output voltage at the output node. Based on a difference between the filtered voltage and the sensed switching voltage, an output current signal is generated that is indicative of an intensity of a current flowing through the inductive load during an estimation time equal to or greater than the first time interval.

### PRIORITY CLAIM

This application claims the priority benefit of Italian Application for Patent No. 102024000012970 filed on Jun. 6, 2024, the content of which is hereby incorporated by reference in its entirety to the maximum extent allowable by law.

### TECHNICAL FIELD

The description relates to current estimation and sensing methods.

For instance, one or more embodiments may be applied in sensing a current flowing through an inductive load in an electronic device, such as, for example, a switched (or switching) converter.

One or more embodiments may be used in applications where, as is the case in the automotive field, for instance, preserving accuracy in operation over the lifetime of an electronic device is a desirable feature.

### BACKGROUND

A pair of power switches in a so-called half-bridge arrangement may be configured to drive electromechanical loads in either one of two configurations: a High-Side Driver (briefly, HSD) configuration in which the load is connected between an output node of the half-bridge and a ground line, and a Low-Side Driver configuration (briefly, LSD) in which the load is connected between a voltage supply line and the output node of the half-bridge.

Power-supply circuits, such as AC/DC or DC/DC switched mode power supplies, are well known in the art. There exist many types of electronic converters, which are mainly divided into isolated and non-isolated converters. For instance, non-isolated electronic converters are the converters of the “buck”, “boost”, “buck-boost”, “Ćuk”, “SEPIC”, and “ZETA” type. Instead, isolated converters are, for instance, converters of the “flyback”, “forward”, “half-bridge”, and “full-bridge” type. Such types of converters are well known to the person skilled in the art.

FIG. 1 is a schematic illustration of a DC/DC electronic converter 20. In particular, a conventional electronic converter 20 comprises two input terminals 200a and 200b for receiving a DC voltage Vin and two output terminals 202a and 202b for supplying a DC voltage Vout. For example, the input voltage Vin may be supplied by a DC voltage source 10, such as a battery, or may be obtained from an AC voltage by means of a rectifier circuit, such as a bridge rectifier, and possibly a filtering circuit. Instead, the output voltage Vout may be used to supply a load 30.

Voltage converters of a non-isolated step-down type are widely used, for example, in order to supply microcontrollers. The ease of use, simplicity, and excellent versatility in the various conditions of input and output voltage render the topology of a buck type one of the most widely used for this type of conversion.

FIG. 2 shows the circuit diagram of a typical buck converter 20. In particular, a buck converter 20 comprises two input terminals 200a and 200b for receiving a DC input voltage Vin and two output terminals 202a and 202b for supplying a regulated voltage Vout, where the output voltage is equal to or lower than the input voltage Vin.

In particular, typically, a buck converter 20 comprises two electronic switches Q1 and Q2 (with the current path thereof) connected (e.g. directly) in series between the input terminals 200a and 200b, wherein the intermediate node between the electronic switches Q1 and Q2 represents a switching node SW. Specifically, the electronic switch Q1 is a high-side switch connected (e.g. directly) between the (positive) terminal 200a and the switching node SW, and the electronic switch Q2 is a low-side switch connected (e.g. directly) between the switching node SW and the (negative) terminal 200b, which often represents a ground GND. The (high-side) switch Q1 and the (low-side) switch Q2 hence represent a half-bridge configured to connect the switching node SW to the terminal 200a (voltage Vin) or the terminal 200b (ground GND).

For example, the switches Q1 and/or Q2 are often transistors, such as Field-Effect Transistors (FETs), such as Metal Oxide Semiconductor Field-Effect Transistors (MOSFETs), e.g. n-channel FET, such as NMOS. Frequently, the second electronic switch Q2 is also implemented just with a diode, where the anode is connected to the terminal 200b and the cathode is connected to the switching node SW.

In the example considered, an inductance L, such as an inductor, is connected (e.g. directly) between the switching node SW and the (positive) output terminal 202a. Instead, the (negative) output terminal 202b is connected (e.g. directly) to the (negative) input terminal 200b.

In the example considered, to stabilize the output voltage Vout, the converter 20 typically comprises a capacitor Cout connected (e.g., directly) between the output terminals 202a and 202b.

As exemplified in FIG. 2, the operation of the circuit 20 is driven by a controller circuit block 22 that can comprise an input node to receive a common pulsed-width modulation, PWM signal, and an amplifier circuitry to provide respective control signals DRV1, DRV2 to the first and second switches Q1, Q2.

In this context, FIG. 3 shows some waveforms of the signals of such an electronic converter, where: waveform a) shows the signal DRV1 for switching the electronic switch Q1; waveform b) shows the signal DRV2 for switching the second electronic switch Q2; waveform c) shows the current IQ1 that traverses the electronic switch Q1; waveform d) shows the voltage signal V_{SW} at the switching node SW (i.e., the voltage at the second switch Q2); and waveform e) shows the current I_{L} that traverses the inductor L.

In particular, when the electronic switch Q1 is closed at an instant t1 (ON state), the current I_{L} in the inductor L increases (substantially) linearly. The electronic switch Q2 is at the same time opened (OFF state). Instead, when the electronic switch Q1 is opened (turned off) after an interval HS_{ON} at an instant t2 (OFF state), the electronic switch Q2 is closed (turned ON), and the current I_{L} decreases (substantially) linearly. Finally, the switch Q1 is closed again after an interval LS_{ON}. In the example considered, the switch Q2 (or a similar diode) is hence closed when the switch Q1 is open, and vice versa.

The current in the inductor I_{L} can thus be used to charge the capacitor Cout, which supplies the voltage Vout at the terminals 202a and 202b. In the example considered, to stabilize the output voltage Vout, the converter 20 typically comprises a capacitor Cout connected (e.g., directly) between the output terminals 202a and 202b.

As exemplified in waveform e) of FIG. 3, the evolution over time of the current I_{L} flowing in the inductor L is equal to the current flowing in the first switch Q1 during the first time interval HS_{ON} and equal to the current flowing in the second switch Q2 during the second time interval LS_{ON}.

DC/DC buck converters as exemplified in FIG. 1 comprise a half-bridge (HB) power stage Q1, Q2 for transferring electrical energy between an input voltage level Vin and an output voltage level Vout. For instance, input voltage level Vin can be about 12 Volts while output voltage level Vout can be about 1.2 Volts. For instance, the load current intensity I_{L} can reach values of about 50 Amperes.

Efficient power supply management is relevant for modern microprocessors, since faster processors use lower supply voltages (e.g., down to 1.2 V) because of thinner gate oxides and higher currents (e.g., even up to 200 Amperes).

One of the most important parameters in a buck converter is the load regulation, which is the capability of the circuit to keep the output voltage Vout stable in response to changing load conditions, which also implies a varying output current Iₒᵤₜ. When the output current Iₒᵤₜ changes over time, overshoots and undershoots can be observed in the output voltage Vout as a function of the ratio ±ΔIₒᵤₜ/ΔT, wherein ΔIₒᵤₜ represents the variation of the current Iₒᵤₜ in a given time interval ΔT. In fact, when the output current Iₒᵤₜ changes, the current I_{L} supplied by the inductor L may be too high or too low, thereby creating a variation of the voltage Vout at the capacitor Cout.

In a manner per se known, the buck converter exemplified in FIGS. 1 and 2 may be used to supply a microcontroller, which may also be configured to drive other loads. These microprocessors may be equipped on-board vehicles. Therefore, current sensing for monitoring the state of power supply stages may be relevant for safety standards.

Existing solutions for sensing the current I_{L} flowing in the inductive load L involve the use of a shunt resistor in series with the inductance L. In the application context considered, such an option is in contrast with reducing power dissipation.

Other known solutions are based on measuring the current flowing in the inductive load L as the sum of currents flowing in the HS and LS transistors during the respective time in which they are turned ON (that is, they are closed). In this case, any known method may be used to provide the two separate measurements. Nevertheless, the reliability of such current sensing method varies with the duty cycle, becoming less reliable for short duty cycle values (e.g., a value of duty cycle about 0.1 causes a HS conduction time as short as 100 ns for a typical switching frequency of 1 MHz, where 1 ns=1 nanosecond=10⁻⁹ seconds). Therefore, the measurement of the current flowing in the HS becomes challenging, even if the LS conduction time (e.g., 0.9 microseconds) remains sufficiently long for accurate current measurement of the low-side current component.

Other existing solutions involve: providing a pin (referred to as a VOS pin) to perform a measurement of the output voltage Vout, thereby providing the possibility of performing an indirect measurement of high-side current; providing a pin (referred to as an LSET pin) for setting an inductive load value, thereby providing a way to obtain an indirect measurement of high-side current by relying on a precise inductor value.

Reference is made to United States Patent Application Publication No. 2010/0060257 A1, incorporated by reference, which discusses a technique for determining an output current of a power converter circuit that samples a voltage of a switch node voltage signal at a midpoint of a low phase of the switch node voltage signal and generates a sensed current signal at least partially based on the sampled switch node voltage and a calibration voltage. In at least one embodiment of this solution, an apparatus includes a current sensing circuit configured to generate a sensed current signal indicative of an average output current of a power converter circuit. The sensed current signal is at least partially based on a sample of a voltage signal on a first node of the power converter circuit. The first node is used to supply a current to an inductor of the power converter circuit.

Reference is made to United States Patent Application Publication No. 20210159788A1, incorporated by reference, which discusses a current estimation circuit configured to estimate current within a power switch, e.g., within a switching voltage converter, using a voltage measured across its load terminals and its on-state resistance. Ringing and other transient anomalies associated with a turn-on transition of the power switch are neglected by ignoring the measured voltage across the power switch for a blanking interval after the transition. During the remainder of the conduction interval of the power switch, the measured voltage is sampled to provide first and second samples. Also, during this interval, a slope of the measured voltage is estimated and tracked. The estimated slope and the first and second samples are combined to produce an estimate of the current for the entire conduction interval of the power switch, including the blanked interval. The estimated slope is used to correct for inaccuracy introduced by not using measured voltage during the blanking interval.

There is a need in the art to adequately address the issues discussed in the foregoing.

### SUMMARY

One or more embodiments may relate to a method.

One or more embodiments may relate to a corresponding circuit.

One or more embodiments may relate to a corresponding electronic converter device.

One or more embodiments may relate to a corresponding processing or control unit.

One or more embodiments may be equipped on board a vehicle.

One or more embodiments may relate to a corresponding current measurement method.

One or more embodiments facilitate providing an estimate of the current flow in a high side transistor of a half-bridge arrangement based on the flow of current sensed in the low-side transistor during the time in which the latter is turned on.

One or more embodiments facilitate providing an accurate reading without introducing any shunt resistance, thereby improving energy efficiency of the power stage.

One or more embodiments use relatively simple means with respect to known solutions involving discrete power MOS transistors for current sensing.

### BRIEF DESCRIPTION OF THE DRAWINGS

One or more embodiments will now be described, by way of non-limiting example only, with reference to the annexed Figures, wherein:

FIG. 1 shows a typical application of an electronic converter;

FIG. 2 shows an example of a buck converter;

FIG. 3 shows exemplary waveforms a) to e) of the converter of FIG. 2;

FIG. 4 is a diagram exemplary of an electronic converter circuit and a current sensing circuit;

FIG. 5 is a diagram exemplary of an evolution over time of signals in one or more embodiments;

FIG. 6 is a diagram exemplary using waveforms a) and b) of principles underlying one or more embodiments;

FIG. 7 is a diagram exemplary using waveforms a) and b) of principles underlying one or more embodiments;

FIG. 8 is a diagram exemplary of principles underlying one or more embodiments;

FIG. 9 is a diagram exemplary of embodiment details for the electronic converter circuit and current sensing circuit of FIG. 4;

FIG. 10 is a diagram exemplary of an evolution over time of signals in one or more embodiments;

FIG. 11 is a diagram exemplary of principles underlying one or more embodiments;

FIG. 12 is a diagram exemplary of embodiment details for the electronic converter circuit and current sensing circuit of FIG. 4;

FIG. 13 is a diagram exemplary of an evolution over time of signals in one or more embodiments;

FIG. 14 is a diagram of extrapolated signals in one or more embodiments;

FIG. 15 is a diagram of an evolution over time of signals in one or more embodiments;

FIG. 16 is a diagram exemplary of a sensing circuit according to one or more embodiments;

FIG. 17 is a diagram exemplary of a portion of the circuit exemplified in FIG. 16;

FIG. 18 is a diagram exemplary of an electronic device equipped with the circuit;

FIG. 19 is a diagram exemplary of an electronic system equipped with the circuit;

FIG. 20 is a diagram exemplary of a vehicle equipped with the circuit; and

FIGS. 21 and 22 are diagrams exemplary of working principles underlying one or more embodiments.

### DETAILED DESCRIPTION

Corresponding numerals and symbols in the different figures generally refer to corresponding parts unless otherwise indicated.

The figures are drawn to clearly illustrate the relevant aspects of the embodiments and are not necessarily drawn to scale.

The edges of features drawn in the figures do not necessarily indicate the termination of the extent of the feature.

In the ensuing description, one or more specific details are illustrated, aimed at providing an in-depth understanding of examples of embodiments of this description. The embodiments may be obtained without one or more of the specific details, or with other methods, components, materials, etc. In other cases, known structures, materials, or operations are not illustrated or described in detail so that certain aspects of embodiments will not be obscured.

Reference to “an embodiment” or “one embodiment” in the framework of the present description is intended to indicate that a particular configuration, structure, or characteristic described in relation to the embodiment is comprised in at least one embodiment. Hence, phrases such as “in an embodiment” or “in one embodiment” that may be present in one or more points of the present description do not necessarily refer to one and the same embodiment.

Moreover, particular conformations, structures, or characteristics may be combined in any adequate way in one or more embodiments.

The references used herein are provided merely for convenience and hence do not define the extent of protection or the scope of the embodiments.

For the sake of simplicity, in the following detailed description a same reference symbol may be used to designate both a node/line in a circuit and a signal which may occur at that node or line.

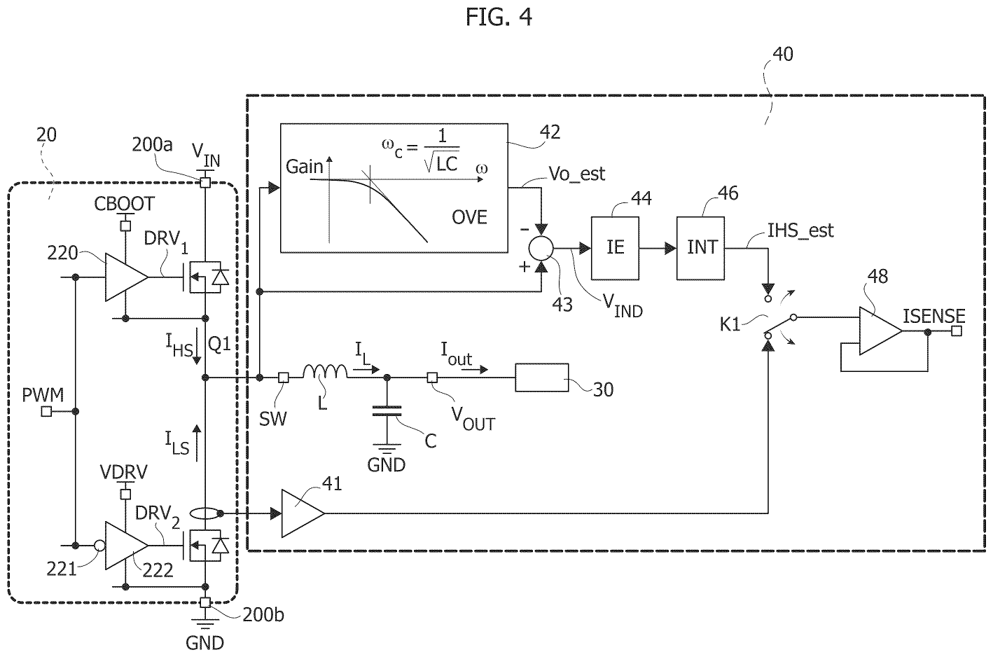

As exemplified in FIG. 4, an electronic converter circuit 20 comprises: a control node PWM configured to receive the pulsed width modulation signal to drive the first Q1 and second Q2 switches of the half-bridge arrangement of switches; a first amplifier circuit 220 coupled to the control node PWM and configured to provide the first drive signal DRV1 to the first switch Q1, to control operation thereof in a manner per se known, and a second amplifier circuit 222 coupled to the control node PWM via an inverter circuit 221 and configured to provide the second drive signal DRV2 to the second switch Q2, to control operation thereof in a manner per se known.

As exemplified in FIG. 4, the electronic converter circuit 20 is coupled to a current sensing circuit 40.

According to the present disclosure, the current sensing circuit 40 comprises: a first current amplifier circuit 41 intermediate the switching node SW of the converter 20 and the second switch Q2 and configured to sense a low side current I_{LS} flowing in the current flow path through the second switch Q2 while it is turned on or closed, namely during at least one portion of the second time interval LS_{ON}; a current estimation cascade of circuit blocks 42, 44, 46 coupled to the switching node SW of the converter 20 and comprising current estimation circuitry configured to estimate the value of the high side current flowing in the first switch Q1, and a selector element K1, such as a switch, configured to be turned on or off based on a timing signal K1, the selector element K1 coupled to a current sense amplifier 48 configured to provide the value of the current flowing in the inductive element L coupled to the converter circuit 20.

It is noted that the value of the inductive element L is in principle not necessarily known to the current sensing circuit 40.

In one or more embodiments, the current sensing amplifier 41 may be per se known. In a manner per se known, the sensing signal provided by the amplifier 41 may be a voltage sensing signal having a certain relation with the low-side current I_{LS}. For instance, the relation may be expressed as 5 mV/A·I_{LS}.

As exemplified in FIG. 4, the current estimation cascade 42, 44, 46 comprises: an output voltage estimator (OVE) circuit block 42 configured to provide an estimated voltage Vo_est indicative of the output voltage Vout at the output of the converter 20; a superposition circuit 43 coupled to the switching node SW and to the output voltage estimator circuit block 42 to provide an estimated voltage drop Vind across inductive element L as a difference between the voltage V_{SW} at the switching node SW and the estimated output voltage Vo_est; an inductance estimator (IE) circuit block 44 coupled to the superposition circuit 43 and configured to provide an estimate of an inverse 1/L of the inductance of the inductive element L; an integrator (INT) circuit block 46 coupled to the inductance estimator circuit block 44 and configured to compute a ratio of the estimated voltage drop Vind and the inverse inductance 1/L, providing an estimated inductive current intensity IHS_est as a result.

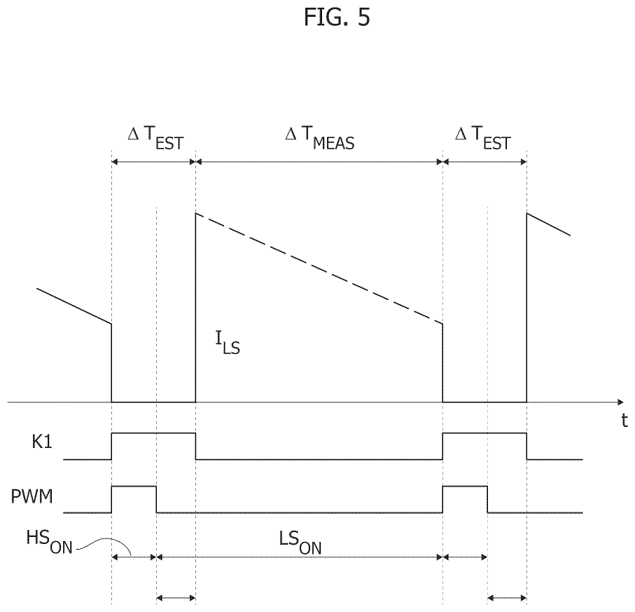

As exemplified in FIG. 5, the selector circuit K1 is configured to provide the measured sensing current I_{LS} through the second switch Q2 during a sensing time interval ΔT_{MEAS} and to provide the estimated inductive current intensity IHS_est during an estimation time interval ΔT_{EST}.

As illustrated in FIG. 5, at the beginning of the second time interval LS_{ON}, the current sense amplifier transitions from turned-off to turned-on, hence it may not be ready to provide the current measurement. Thereby, the estimation time interval K1 can be greater than the on-time HS_{ON} of the first switch Q1. For instance, the estimation time interval K1 may be equal to the sum of the first on-time interval HS_{ON} and of a settling time interval for the current sense amplifier to yield the measurement result. For instance, the settling time may be about 200 ns (1 ns=1 nanosecond=10⁻⁹ seconds).

As exemplified herein, the output voltage estimator circuit block 42 comprises a filter circuit having a cut-off angular frequency ω_{C} that is indicative of the actual cut-off frequency of the LC circuit coupled to the switching node SW. For instance, a 2^{nd} order low pass filter, known per se, may be exploited for the output voltage estimator circuit block 42 in one or more embodiments. For instance, the cut-off frequency f_{c} of the output voltage estimator circuit block 42 may be set in a range of 15 kHz to 17 kHz, preferably 16.0 kHz (1 kHz=1 kiloHertz=10³ Hertz) considering conventional values for inductance L of about 0.15 microHenry and capacitance C of about 660 microFarad.

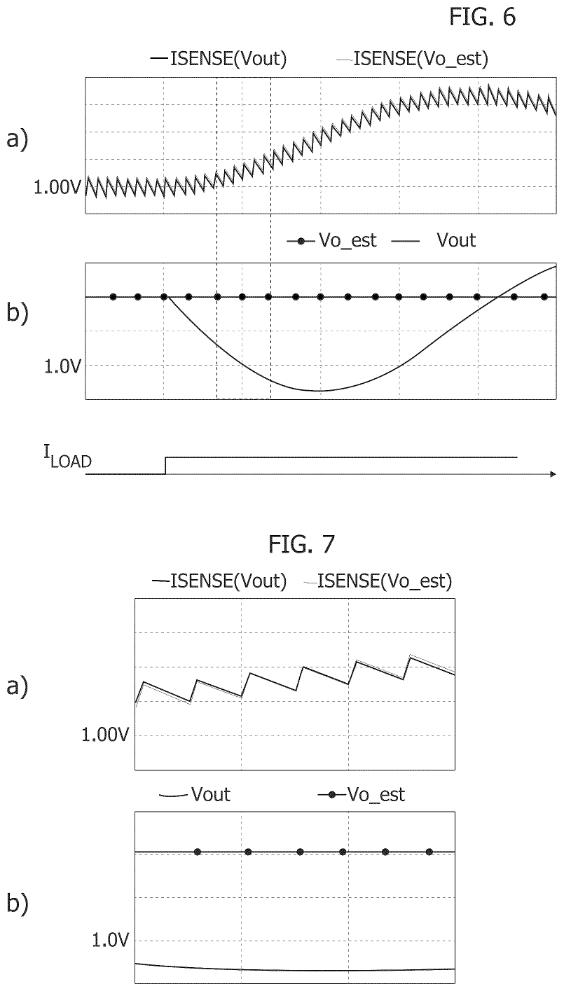

As exemplified in FIG. 6, even if there are few differences among the values of the estimated output voltage Vo_est and the actual output voltage Vout, as reported in wavform b) of FIG. 6, the estimated current ISENSE(Vo_est) has value close to the actual ones ISENSE(Vout), as reported in waveform a) of FIG. 6.

FIG. 7 is an enlarged view of a portion of the diagrams exemplified in FIG. 6. As illustrated in FIG. 7, waveform b) presents a comparison of estimated Vo_est and actual Vout output voltage signals and waveform a) presents a comparison of the output voltage ISENSE of the buffer 48 based on the estimated ISENSE(Vo_est) or actual ISENSE(Vout) which in both cases reaches output current values about 20 Amperes and constant on-time during a time interval of 4 microseconds.

As exemplified in FIG. 4, the output signal ISENSE may be indicative of the current flowing in the inductive load L thanks to a relationship (per se known) that may be expressed as: ISENSE=5 mV/A·I_{L}

As exemplified herein, the inductance estimator circuit block 44 comprises an automatic gain control (AGC) loop whose gain is indicative of the inductance value 1/L and whose value is continually refreshed at every PWM cycle.

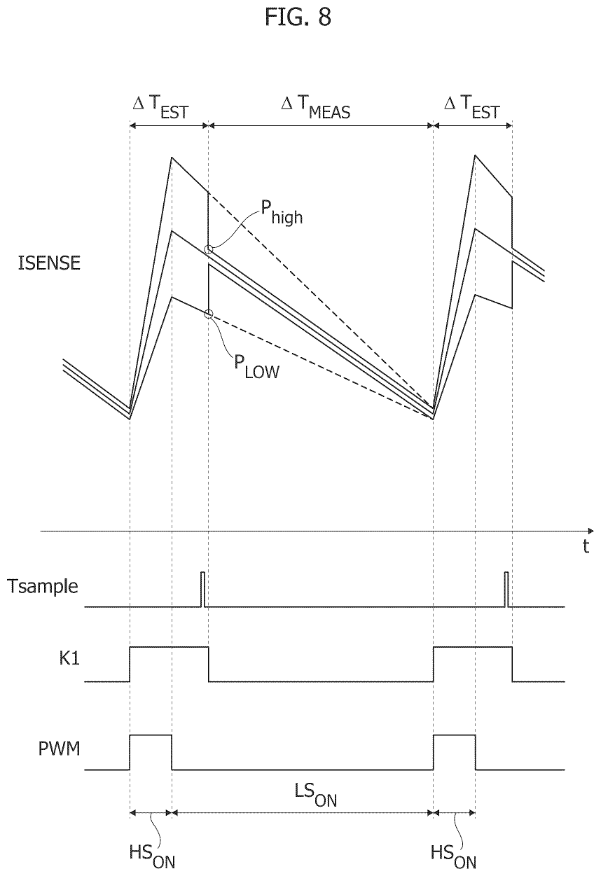

FIG. 8 is exemplary of principles underlying operation of the circuit block 44.

As exemplified in FIG. 8, the AGC starts from an initially approximated gain value (for example, after power up) and it can take several PWM cycles (e.g., 100 cycles) before settling to a stationary gain value. For instance, the AGC is partially digital, and it can retain the gain value in digital volatile memory for as long as the power supply is up.

As exemplified in FIG. 8: the AGC loop samples the value of the output current sensing signal ISENSE in the time interval in which the selector circuit K1 is closed while the first switch Q1 is open, specifically very close to the time in which the selector K1 is switched, obtaining an initial estimate L0. In the case where the initial estimate L0 is too low with respect to the actual inductance value L, the output ISENSE of the buffer 48 presents a vertical drop Phigh in the current values; therefore, the AGC loop decreases the gain. In the case where the initial estimate L0 is too high with respect to the actual inductance value L, the output ISENSE of the buffer 48 presents a vertical increase Plow in the current values; therefore, the AGC loop increases the gain. The process above is iterated until a comparison between the output sensing signal ISENSE before and after the sampling time Tsample of the AGC loop can be considered negligible.

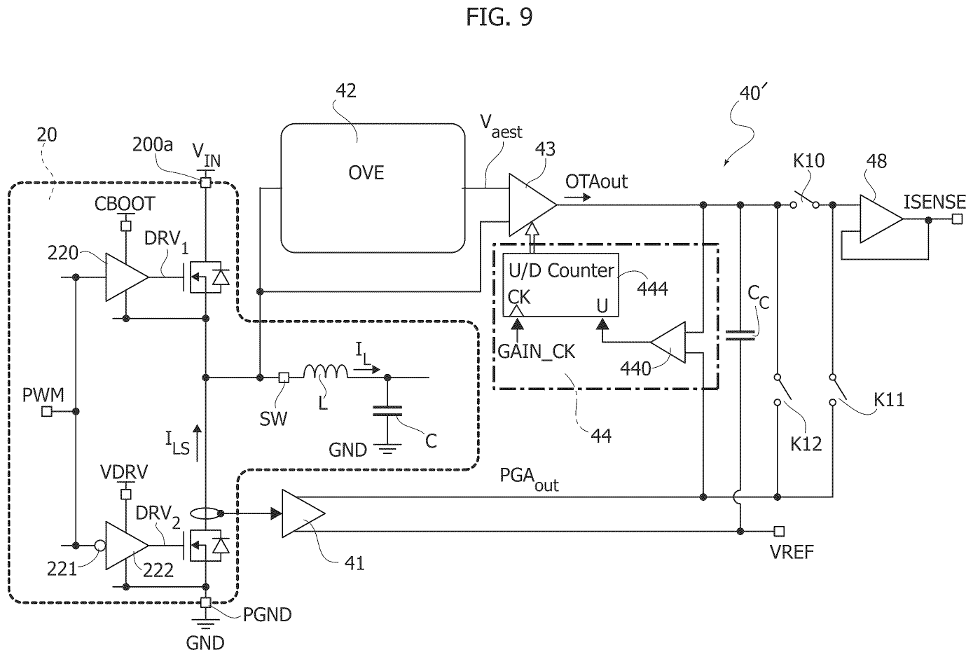

FIG. 9 is a diagram exemplary of a way to implement the updating of the gain of the circuit block 44 using the principles exemplified in FIG. 8.

In a circuit 40′ as exemplified in FIG. 9: the first sensing amplifier 41 comprises a programmable gain amplifier (PGA) configured to output a voltage PGAout indicative of the current flowing in the second switch Q2 during the second time interval LS_{ON}; and the output voltage estimator (OVE) circuit block 42 is coupled to a (e.g., transconductance) amplifier 43 that provides a current output signal OTAout.

For instance, the inductance estimator (IE) circuit block 44 comprises: a comparator circuit 440 coupled to the circuit block 43 and to the first sensing circuit 41, the comparator configured to output a first (e.g., “1” or “true”), respectively second (e.g., “0” or “false”), logic value in response to the measured current I_{LS} received from the first sensing circuit 41, and a digital counter 444 coupled to the comparator 440 and configured to count, at a clock signal edge GAIN_CK, incrementally or decrementally based on the logic value U received from the comparator 440.

For instance, the digital counter 444 outputs a signal gm_control, e.g., comprising 9 bits and whose values can range (from 0 to 511, for example) and configured to vary the gain of the OTA 43 in a range, e.g., for example, from 0 to 1.31 μA/V.

As exemplified in FIG. 9, the circuit 40′ further comprises: a first selector switch K10 interposed the output of the circuit block 43 and the input of the buffer 48 and configured to be made selectively conductive in response to a first switching signal K10 having a first logic value (e.g., “1” or “true”); a second selector switch K11 interposed the output of the current sensing amplifier circuit 41 and the input of the buffer 48 and configured to be made selectively conductive in response to a second switching signal K11 having a first logic value (e.g., “1” or “true”); and a third selector switch K12 interposed the output of the circuit block 43 and the output of the current sensing amplifier circuit 41 and configured to be made selectively conductive in response to a third switching signal K12 having a first logic value (e.g., “1” or “true”).

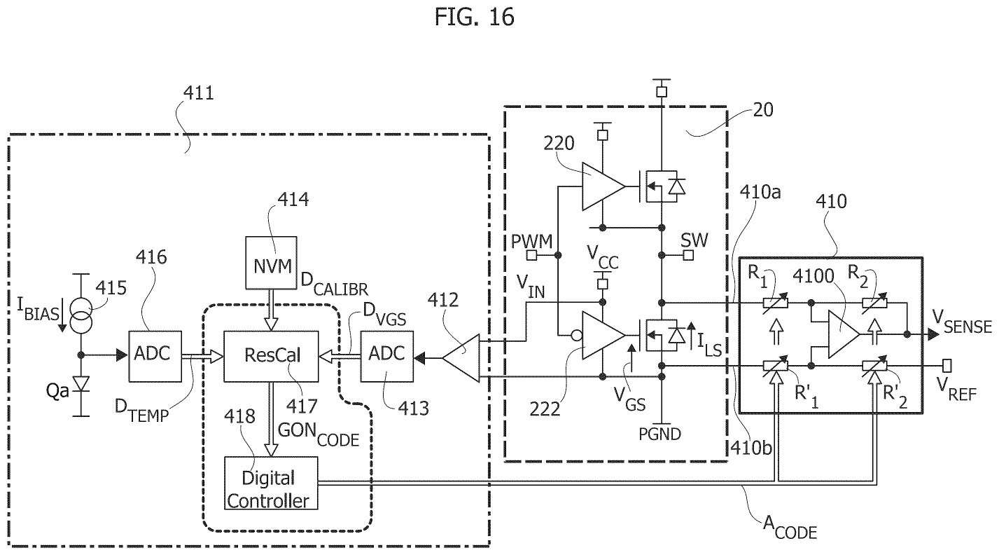

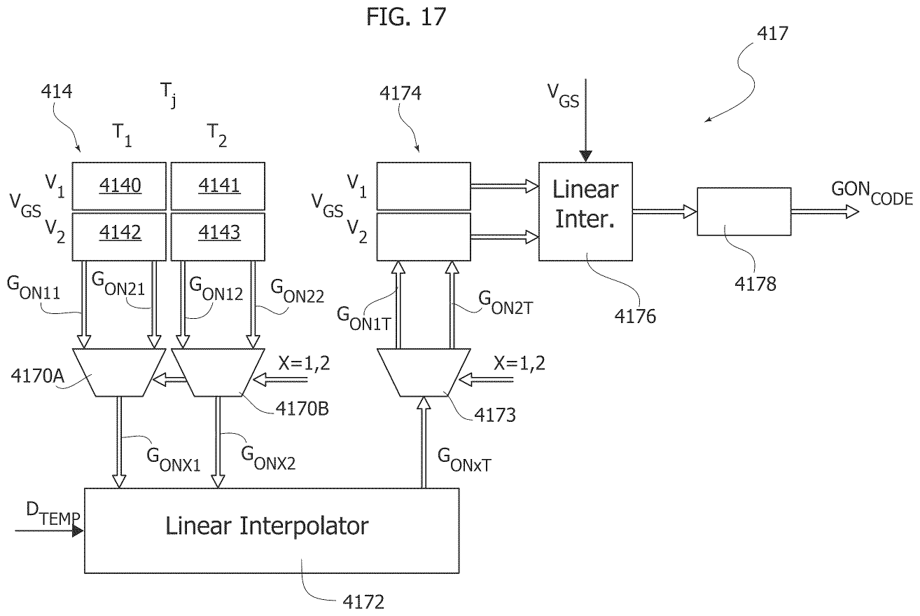

In the example illustrated in FIG. 9 it may be possible to use a calibrated current sensing amplifier 41 as discussed in the following (mainly with reference to FIGS. 16 and 17). An improved accuracy in the measurement of the second switch current I_{LS} may advantageously provide an improved accuracy in the current estimation cascade 42, 43, 44, 46, 48, as discussed in the following.

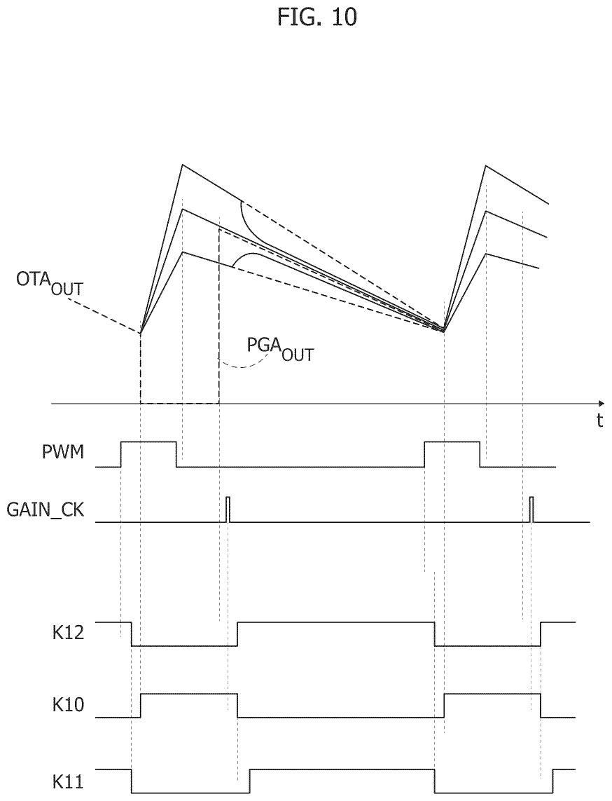

FIG. 10 is a temporal diagram exemplary of signals which may be used in connection with the circuit exemplified in FIG. 9.

As exemplified in FIG. 10: at the first (e.g., rising) edge of the drive signal PWM, the second selector switch K11 is turned off and also the third selector switch K12 is turned off, thereby coupling the amplifier 41 to the comparator 440 and decoupling it from the output buffer 48. As soon as it is made available from the current sensing amplifier circuit 41, the value of the current sensing curve PGAout is sampled at the edge of clock signal GAIN_CK. Subsequently, the AGC loop is driven by the digital counter 444 to increase or decrease the gain of the OTA 43 based on the result of the comparison 440 among the sampled sensed current value PGAout and the output OTA signal OTAout.

For instance, after 100 cycles of iteration, the values of the signals PGAout and OTAout at the sample time instant GAIN_CK are about the same.

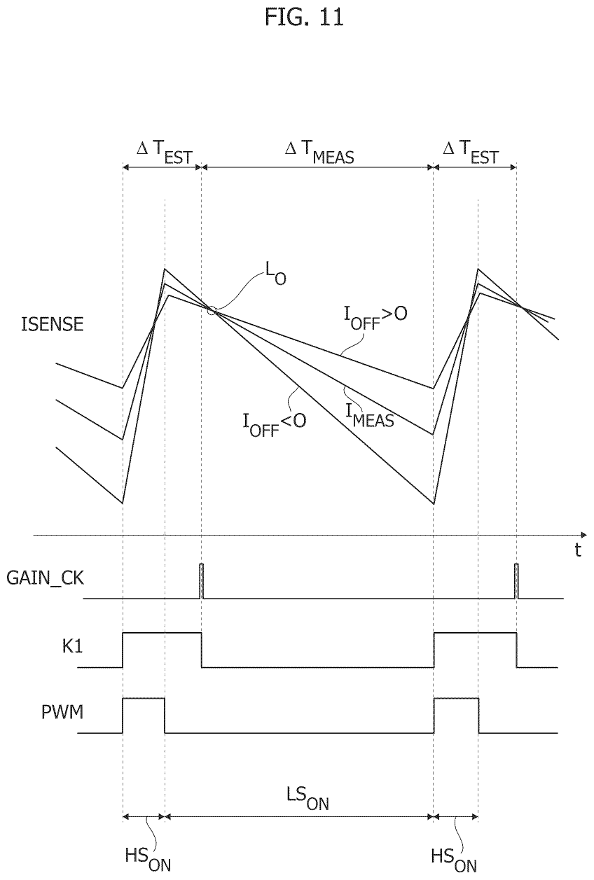

FIG. 11 is a diagram of principles underlying one or more embodiments that consider non-linearities in the circuit exemplified in FIG. 9.

As exemplified in FIG. 9, in the presence of a negative or positive (unknown and unwanted) offset current, even if there is a very good match of the value L0 at the sampling clock edge, the evolution over time of the estimated current becomes appreciably different from the actual measured one I_{MEAS}.

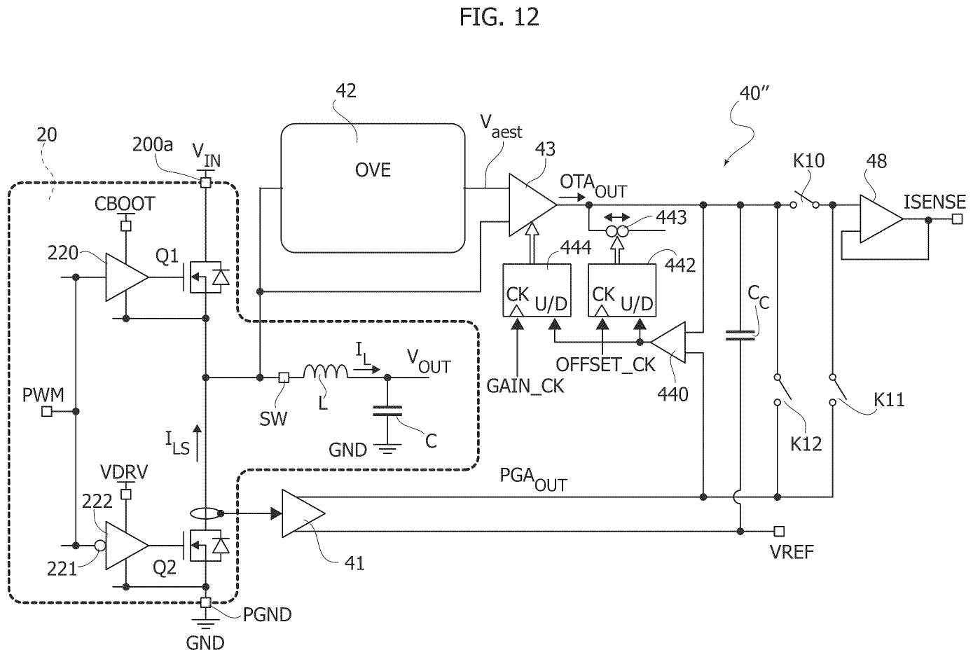

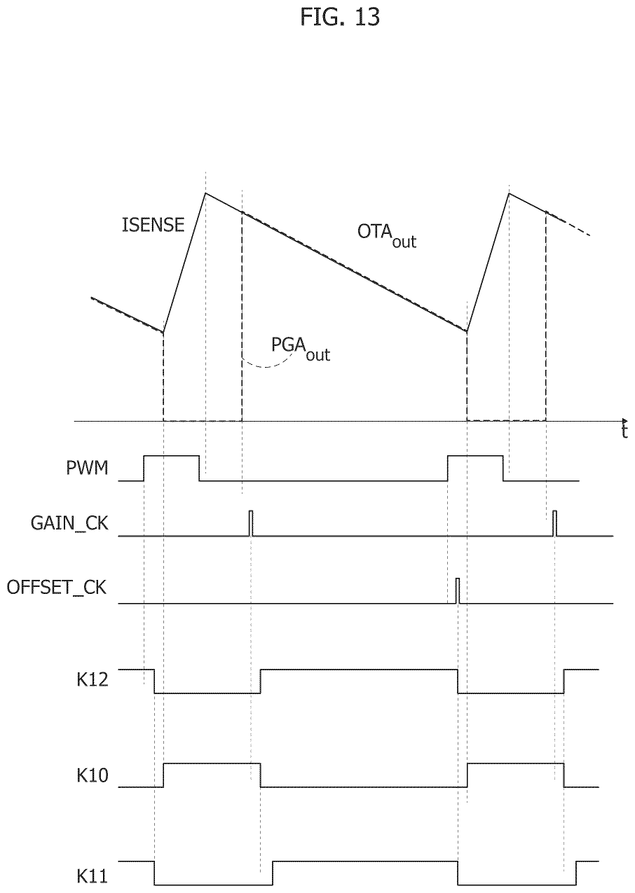

As exemplified in FIG. 12, a circuit 40″ that compensates for the current offset of circuit block 43 comprises a further digital counter 442 coupled to the comparator circuit 440 and to a programmable current generator 443 coupled to the output of the OTA amplifier 43, the programmable current generator 443 configured to generate a current based on the digital count indicated by the further digital counter 442. For instance, the further digital counter 442 is configured to produce a multi-bit further digital counter signal, e.g., 10-bit signal whose values can vary in a range, for example, from −512 to 511, in order to drive the current generator 443 to generate a current intensity in a range of, for example, from −2.5 μA to +2.5 μA.

As exemplified in FIG. 13, operation of the circuit 40″ as shown in FIG. 12 is the same as that already illustrated in FIG. 10 with the addition of a further clock signal OFFSET_CK that drives the further digital counter 442 to sample the value of the measured current signal PGAout and that of the estimated output value OTAout to perform a comparison therebetween and output a logic value that determines whether the digital counter increments or decrements the count, increasing or decreasing the amplitude of the programmable current generator 443 in a corresponding way.

In one or more embodiments the comparator 440 may comprise an auto-calibrating comparator circuit or self-calibrating comparator circuit (known per se) in order to take into account the introduction of further non-idealities. For instance, the circuit architectures 40, 40′, 40″ are configured to provide space to perform auto-calibration of the comparator circuit 440, in a manner per se known.

As exemplified in FIG. 13, the further counter 442 may be activated a reduced number of times (e.g., once every four periods of the PWM signal) with respect to the first counter 444 since the variation over time of the offset that must be compensated can be considered slower than the gain variations tracked by the AGC loop.

As exemplified in FIG. 13, it may be possible to skip asserting the third switch K12 to the first logic value once in a while (e.g., once every four cycles) in order to perform the offset compensation and trigger the further counter 442 correspondingly.

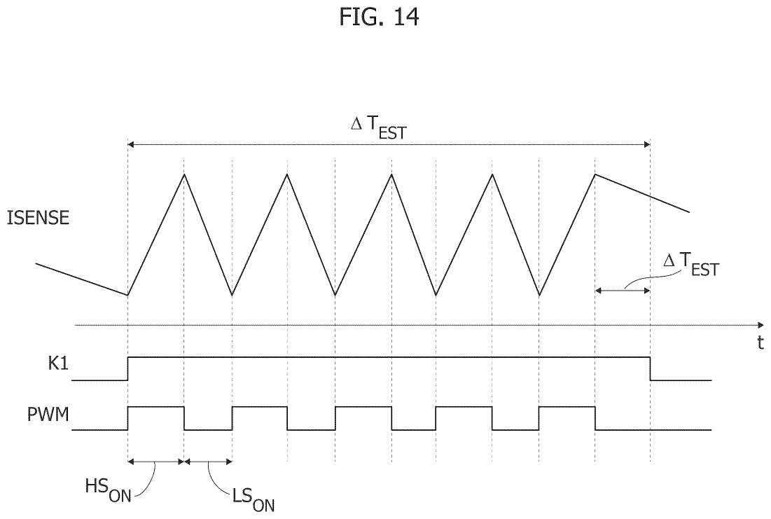

As exemplified in FIG. 14, in case the second time interval LS_{ON} lasts shorter than a fixed delay time (e.g, 200 ns where 1 ns=1 nanosecond=10⁻⁹ seconds) relative to the settling time of the amplifier circuit 41, the circuit 40, 40′, 40″ outputs an estimate of the current flowing through the inductive element L for up to a given number (e.g., ten) of PWM cycles; therefore, also in a transient condition in which the system reacts to fast load/line transients, and the time interval LS_{ON} is relatively short, the estimated current ISENSE may remain valid for a finite number (e.g., ten) of PWM cycles.

As exemplified herein, an advantage of the circuit 40, 40′, 40″ as per the present disclosure facilitates reconstructing an evolution over time of the current flowing in the inductive element L of the converter 20 even in case both switches Q1, Q2 of the half-bridge arrangement are turned off for a time interval much longer than the dead time.

As exemplified in FIGS. 9 and 12, the current sensing amplifier circuit block 41 is coupled to a reference voltage line VREF which is further coupled to the output of the OTA 43 via a capacitive element Cc, e.g., having a capacitance of about 10 pF (1 pF=1 picoFarad=10⁻¹² Farad).

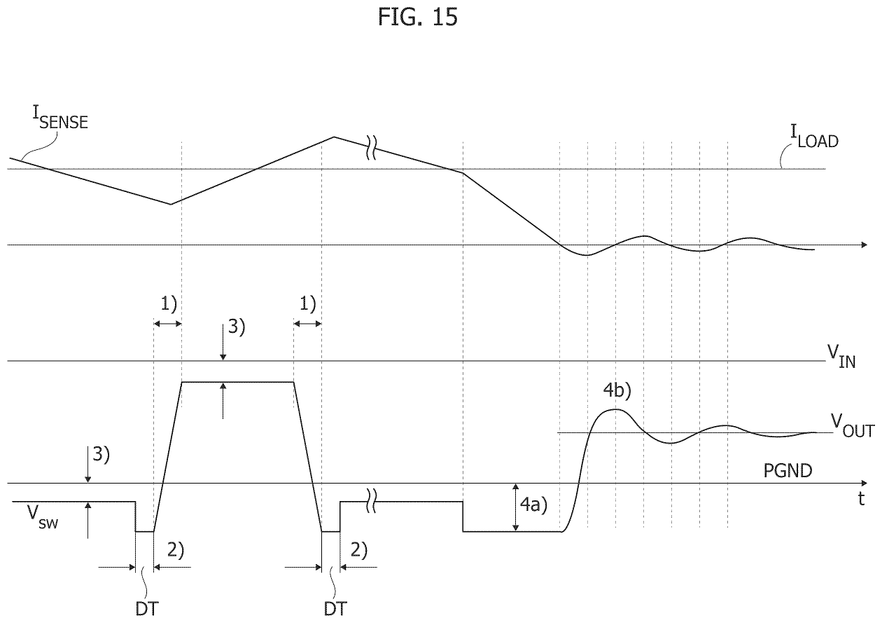

As exemplified in FIG. 15, the sensing method comprises: in response to both HS and LS being turned OFF, a (digital) counter is triggered to start counting; during the time in which the counter is actively counting, the loop keeps following the load current value via the active OTA (transconductance) amplifier; as soon as the counter reaches a pre-set value (e.g., 12 μs, where 1 μs=1 microsecond=10⁻⁶ seconds), a comparator detects whether the voltage at the switching node SW has changed sign (e.g., from negative to positive); as a result of the comparator detecting a sign change for the voltage at the switching node, the voltage output of the amplifier 41 is forced to V_{REF} (corresponding to a zero current signal at the ISENSE pin).

As exemplified in FIG. 15, the circuit facilitates ensuring the accuracy of the reconstructed current even in presence of the following non-idealities: 1) Voltage slopes and delay at switching node SW; 2) Dead times DT of half-bridge switches Q1, Q2; 3) Voltage drops on half-bridge switches Q1, Q2; and 4) Arbitrary voltage waveforms at switching node SW during high impedance state of half-bridge switches Q1, Q2, particularly: 4a) Recirculation on the body diode of switches Q1, Q2; 4b) Dumped oscillation of switching node voltage signal V_{SW} at current turn off.

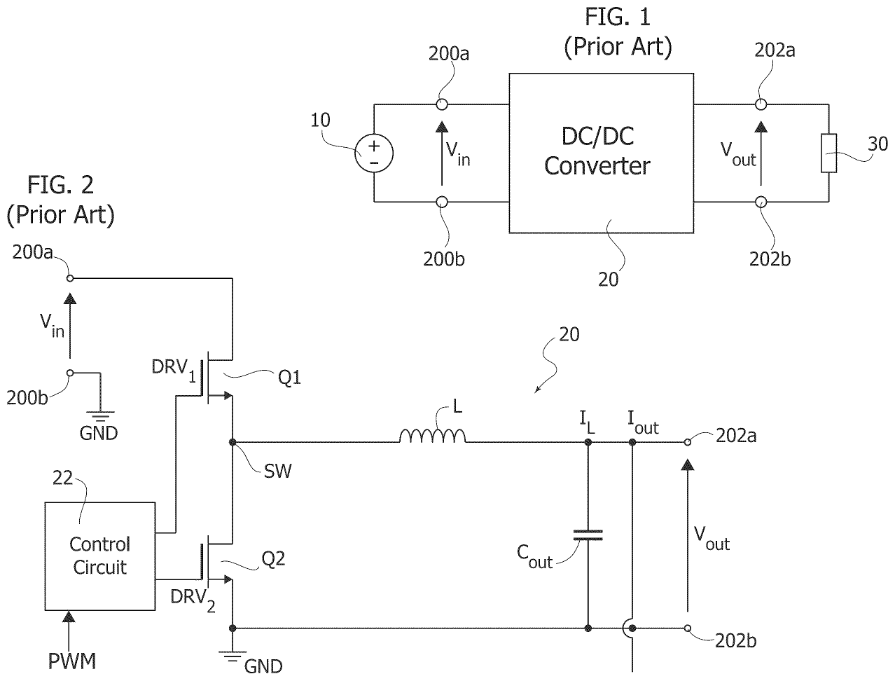

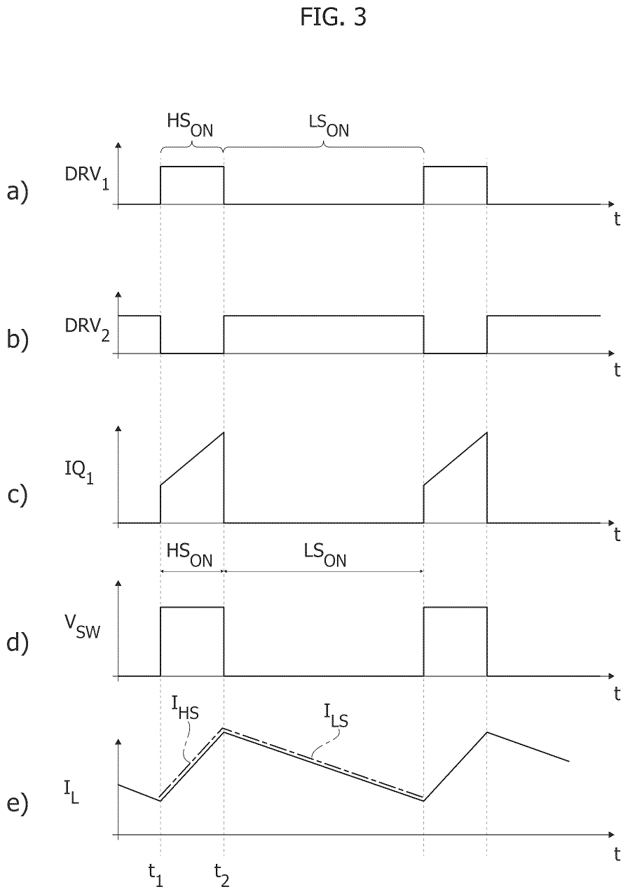

A method as exemplified in FIGS. 1 to 15 comprises: coupling a high-side switch Q₁ between a high-side reference node V_{IN} and a switching node SW; and coupling a low-side switch Q₂ between the switching node SW and a low-side reference node PGND.

For instance, the high-side switch comprises a high-side control terminal configured to receive a high-side control signal PWM, DRV1 as well as a current flow path therethrough between the high-side reference node and the switching node, the high-side switch being configured to be made conductive in response to the high-side control signal having a first logic value during a first time interval HS_{ON}.

For instance, the current flow path through the high-side switch provides a high-side current flow line I_{HS} between the high-side reference node and the switching node.

For instance, the low-side switch comprises a low-side control terminal configured to receive a low-side control signal PWM, DRV2 as well as a current flow path therethrough between the switching node and the low-side reference node, the low-side switch being configured to be made conductive in response to the low-side control signal having said first logic value during a second time interval LS_{ON}.

For instance, the current flow path through the low-side switch provides a current flow line I_{LS} between the switching node and the low-side reference node.

As exemplified in FIGS. 1 to 15, the method further comprises: coupling an inductive element L to the switching node and to an output node Vout configured to be coupled to a load 30; sensing the switching voltage V_{SW} at the switching node, providing said sensed switching voltage to a filter circuit 42 configured to provide a filtered voltage Vo_est based on said sensed switching voltage, the filtered voltage indicative of the output voltage at said output node; and based on a difference V_{IND} between said filtered voltage and said sensed switching voltage, providing 43, 44, 46 to user circuitry 48 an output current signal IHS_est, ISENSE indicative of the intensity of a current through the inductive load during an estimation time ΔT_{EST} equal to or greater than said first time interval.

As exemplified in FIGS. 1 to 15, said filter circuit comprises a filter circuit having a cut-off frequency (e.g., about 16.0 kHz) based on an expected inductance value of the inductive element.

As exemplified in FIGS. 1 to 15 as well as FIG. 16, the method further comprises: receiving, via a measurement circuit 41, a current measurement signal PGAout indicative of a low-side current I_{LS} flowing through said current flow path through said low-side switch; via a transconductance amplifier, OTA circuit 43 having a variable gain, applying transconductance amplification to the difference of said filtered voltage and said sensed switching voltage, obtaining an amplified filtered current signal OTAout as a result.

For instance, the variable gain of said transconductance amplifier, OTA circuit is based on a stored digital code set via a digital counter circuit 444.

As exemplified in FIGS. 9 to 13, setting said digital code via said digital counter circuit comprises: initiating said digital code of the digital counter to an initial digital code value; at lapse GAIN_ck, K12 of said estimation time, performing a comparison 440 of said amplified filtered current signal and of said current measurement signal; incrementing, respectively decrementing U/D, said digital code as a result of said current measurement signal exceeding, respectively failing to exceed, said amplified filtered current signal; and varying the variable gain of said transconductance amplifier, OTA circuit based on said digital code incremented or decremented via said digital counter.

As exemplified in FIGS. 12 to 15, for instance: said transconductance amplifier, OTA circuit has an offset current, and the method further comprises: generating an offset compensating current via a programmable current generator circuit 443 having a programmable current intensity; and superimposing said offset compensating current to said amplified filtered current signal.

For instance, the programmable current intensity of said offset programmable current generator circuit is based on a stored further digital code set via a further digital counter circuit 442, as exemplified in FIG. 12.

As exemplified in FIGS. 12 to 15, setting said further digital code via said further digital counter circuit comprises: initiating said digital code of the further digital counter to an initial digital code value equal to zero; right before the start OFFSET_CK of an estimation time interval ΔT_{EST}, performing a comparison of said amplified filtered current signal and of said current measurement signal; decrementing, respectively incrementing U/D, said further digital code as a result of said current measurement signal exceeding, respectively failing to exceed, said amplified filtered current signal; and varying the programmable intensity of said offset compensating current generator circuit based on said further digital code incremented or decremented via said further digital counter.

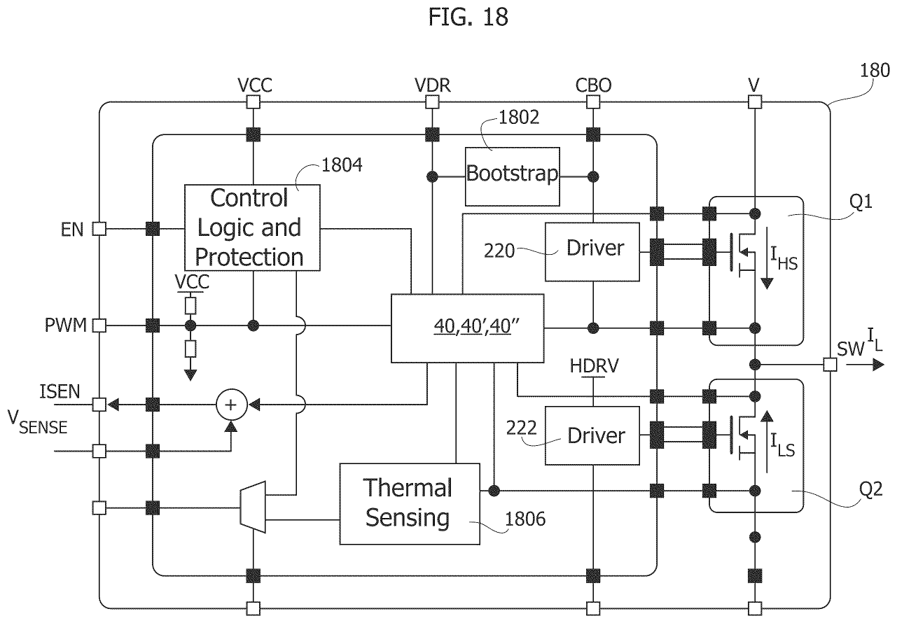

As exemplified in FIGS. 1 to 15, during said estimation time interval, the method comprises coupling K1; K10, K11, K12 an output of said OTA circuit to an output buffer 48 to provide the output current signal to user circuits (such as those exemplified in FIGS. 18 to 20), while during the remaining time (outside of the estimation time interval), the method comprises coupling K1; K10, K11, K12 said measurement circuit 41 to the output buffer to provide the output current signal to user circuits (such as those exemplified in FIGS. 18 to 20).

As exemplified in FIGS. 1 to 15 as well as FIG. 16, measuring a current measurement signal PGAout, Vsense comprises: coupling one input node 410a of a further programmable gain OTA amplifier circuit 410 to said switching node and the other input node 410b of said OTA circuit to said low-side reference node, measuring a voltage drop across the low-side switch, and applying said sensed voltage across a set of variable resistive elements R1, R2 configured to vary the gain of the further OTA circuit, providing said current measurement signal as a result.

For instance, the resistance of at least one variable resistive element in the set of variable resistive elements is set via an error compensating digital code Acode set via an error compensation circuit 411.

As exemplified in FIGS. 16 and 17, the error compensation circuit comprises: a non-volatile memory (NVM) circuit 414 having stored thereon parameter values Gon11, Gon12, Gon21, Gon22 of the low-side switch collected during manufacturing thereof at a plurality of temperature and operating/driving voltage values; an operating voltage sensing circuit 412, 413 configured to sense an operating/driving voltage Vgs at the control terminal of the low-side switch during measurement 41 of the current measurement signal; a temperature sensing circuit 415, 416 configured to sense an operating temperature Tj of the low-side switch during measurement of the current measurement signal; and a resistance calculation (ResCal) circuit 417, 418 configured to provide said error compensating digital code based on said stored low-side switch parameter values, said sensed operating/driving voltage and said sensed operating temperature.

As exemplified in FIGS. 16 and 17, the process parameters stored on the non-volatile memory comprise on-conductance values of the low-side switch collected by varying an operating temperature for a given operating voltage and by varying the operating/driving voltage at a given operating temperature.

As exemplified in FIGS. 16 and 17, the resistance calculation circuit 417 comprises: a first linear interpolation circuit 4172 configured to perform linear interpolation of sets of said on-conductance values collected at a given operating voltage and stored on the non-volatile memory, providing as a result a set of interpolated curves indicative of an evolution over temperature of the on-conductance of the low-side switch, the first linear interpolator circuit further configured to extract from the set of interpolated curves a set of on-conductance values Gon1T, Gon2T at the sensed temperature signal, and a second linear interpolation circuit 4176 coupled to the first linear interpolator circuit to receive the extracted set of on-conductance values therefrom, the second linear interpolation circuit configured to perform linear interpolation of said extracted on-conductance values, providing as a result an interpolated curve indicative of an evolution over operating voltage of the on-conductance of the low-side switch, the second linear interpolator circuit further configured to extract from the interpolated curve an on-conductance values GonVT at the sensed operating voltage.

A circuit as exemplified in FIGS. 1 to 15 comprises: a high-side switch coupled to a high-side reference node and to a switching node, in which the high-side switch comprises a high-side control terminal configured to receive a high-side control signal as well as a current flow path therethrough between the high-side reference node and the switching node, the high-side switch being configured to be made conductive in response to the high-side control signal having a first logic value during a first time interval, wherein the current flow path through the high-side switch provides a high-side current flow line between the high-side reference node and the switching node; a low-side switch coupled to the switching node and to a low-side reference node, in which the low-side switch comprises a low-side control terminal configured to receive a low-side control signal as well as a current flow path therethrough between the switching node and the low-side reference node, the low-side switch being configured to be made conductive in response to the low-side control signal having said first logic value during a second time interval, wherein the current flow path through the low-side switch provides a current flow line between the switching node (SW) and the low-side reference node; an inductive element coupled to the switching node and to an output node configured to be coupled to a load; a filter circuit coupled to said switching node to sense a switching voltage therefrom, the filter circuit configured to provide a filtered voltage based on said sensed switching voltage, the filtered voltage indicative of the output voltage at said output node; signal processing circuitry coupled to the filter circuit, the signal processing circuitry configured to, based on a difference between said filtered voltage and said sensed switching voltage, provide to user circuitry an output current signal IHS_est, ISENSE indicative of the intensity of a current through the inductive load during an estimation time ΔT_{E}ST equal to or greater than said first time interval HS_{ON} according to the method exemplified in FIGS. 1 to 15.

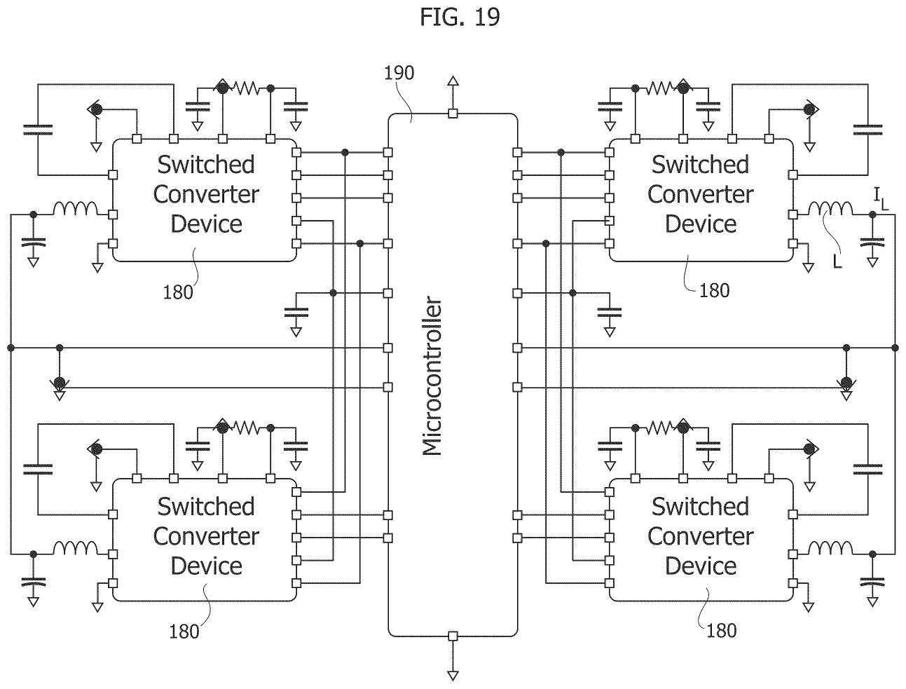

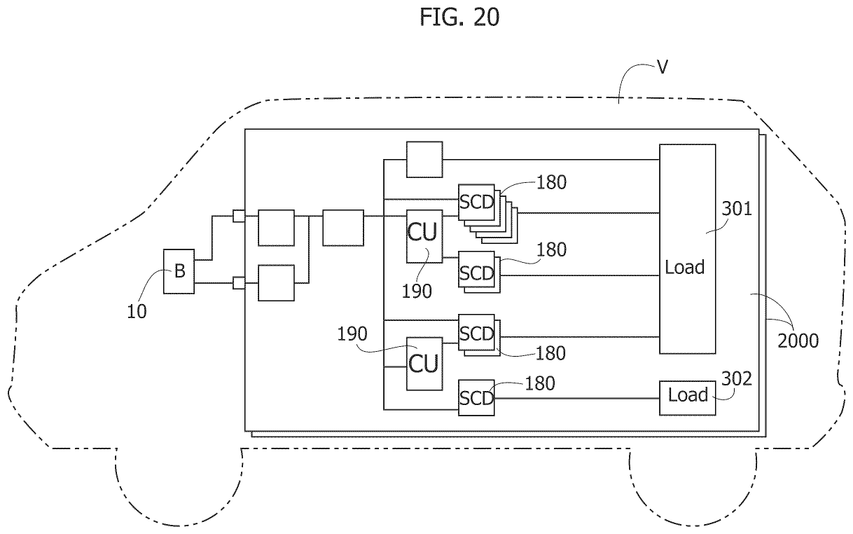

A switched converter device (SCD) 180 and controller unit 190 as exemplified in FIG. 18 or 19 comprises a circuit 40, 40′, 40″ as exemplified in FIGS. 1 to 15 and a battery (B) 10 (see, FIG. 20) configured to provide a voltage supply level to said reference node VI or a ground node PGND configured to provide a ground voltage level to said reference node. The switched converter device further comprises control circuitry configured to provide said control signal to the low-side and high-side switches of the circuit.

As exemplified in FIG. 19, an electronic control unit (ECU) comprises: at least one switched converter device 180 as exemplified in FIG. 18 or at least one circuit 40, 40′, 40″ as exemplified in FIGS. 1 to 15; a microcontroller 190 coupled to the at least one switched converter device or to the at least one circuit and configured to provide said control signal thereto; and at least one load 30; 301, 302 (see, also, FIG. 20) configured to be coupled to the circuit to receive a regulated output voltage Vout therefrom.

As exemplified in FIG. 20, the ECU is mounted onboard a vehicle V such as a battery powered automotive vehicle.

As discussed in the foregoing, an accuracy of the estimation cascade 42, 43, 44, 46, 48 can be a function of the non-idealities of the components involved as well as of the accuracy and timing of the current sensing amplifier 41 in providing the signals for the measured current I_{LS}.

FIG. 16 is an exemplary arrangement of a current sensing amplifier circuit block 41 which may be used in the circuit 40, 40′, 40″ as per the present disclosure or also in a conventional half-bridge circuit 20 to detect a current flowing through any one of the switches Q1, Q2.

As exemplified in FIG. 16, a sensing circuit block 41 comprises: a programmable gain amplifier (PGA) 410 comprising a first PGA input node 410a coupled to the switching node SW and a second PGA input node 410b coupled to a terminal of a switch Q1, Q2 whose on-resistance Ron is under monitoring, for instance the second switch Q2; the PGA further comprises a first output node Vsense configured to provide a signal indicative of the current flowing across the switch Q2 and a second output node V_{REF} configured to be coupled to a reference signal V_{REF}. A compensation circuit block 411 is coupled to switch under monitoring Q2 via the respective driver 222 and coupled to the PGA 410 to provide thereto compensation of non-idealities, as discussed in the following.

As appreciable to those of skill in the art, a gain value PGA gain of the PGA circuit 410 can be expressed as:

$${PGA}_{GAIN} = \frac{{R}_{2}}{{R}_{1}} = \frac{{R}_{2}^{′}}{{R}_{1}^{′}}$$

As exemplified in FIG. 16, the sense voltage signal Vsense is based on a reference voltage VREF and on a known expression, for instance:

$${V}_{SENSE} = {V}_{REF} + 5 mV / A \cdot {I}_{LS}$$

As the sense signal is also a function of the on-resistance Ron of the switch Q2 and the current flowing through the switch Q2. Therefore, the expression above can be rewritten as:

$${V}_{SENSE} = {V}_{REF} + \frac{5 mV}{A} \cdot {I}_{LS} = {V}_{REF} + {R}_{ON} {I}_{LS} P G {A}_{GAIN}$$

which yields

$${PGA}_{GAIN} = \frac{{R}_{2}}{{R}_{1}} = \frac{5 mV / A}{{R}_{ON}} = {G}_{ON} 5 mV / A$$

As exemplified in FIG. 16, the compensation circuitry 411 is configured to modify variable resistances of resistive elements R₁, R₂ in such a way that the above equation is respected throughout PVT variations of power MOS RON.

Specifically, it may be possible to vary the direct gain by varying a first resistive element R1 or the inverse gain by varying a second resistive element R2 of the PGA circuit 410.

As exemplified in FIG. 16, the PGA circuit 410 comprises a differential amplifier 4100 having either a set of variable resistive elements R1, R2 coupled to a first input node and output node to control a direct gain of the PGA circuit 410 or a second set of variable resistive elements R1′, R2′ coupled to a second input node and to the output node to control an inverse gain of PGA circuit 410, as discussed in the following.

As exemplified in FIG. 16, the compensation circuit block 411 comprises: a differential amplifier 412 comprising a first input node 412a and a second input node 412b coupled across the driver 222 of the second switch Q2 to detect a drive (e.g., gate) signal DRV2 thereof; and a first analog-to-digital converter (ADC) circuit 413 coupled to an output node of the differential amplifier 412, the first ADC circuit 413 configured to output a digital signal D_{VGS} indicative of the “real-time” value of an on-resistance R_{ON} of the second switch Q2 at the operative temperature and supply voltage VCC. Aa data storage circuit 414, such as a non-volatile memory NVM, is configured to store calibration data Dcalibr for correcting the Ron measurement, as discussed in the following. For instance, the data storage circuit 414 stores data output from the production line after the assembly of the switch Q2 together with its driver (in order to store data related to system-in-package, SiP non-idealities). A programmable current generator 415 is coupled to a diode Qa referred to ground, and a second ADC circuit 416 is coupled to the programmable current generator 415 and configured to apply analog-to-digital conversion thereto, providing a second digital current signal Dtemp indicative of the temperature of the switch Q2. A linear interpolator 417 is coupled to the first ADC circuit 413 to receive the first digital signal Dvgs therefrom, coupled to the data storage circuit 414 to receive the calibration signal Dcalibr therefrom and coupled to the second ADC circuit 416 to receive the second digital signal Dtemp therefrom. The linear interpolator 417 is configured to provide a gain code GONcode based on the digital signals Dvgs, Dtemp and Dcalibr received, as discussed in the following with reference to FIG. 17. A digital controller circuit 418 is coupled to the linear interpolator 417 to receive the gain digital code GONcode therefrom and configured to provide the variation of the value of the resistance R1, R2 of the PGA amplifier 410 based on the received gain digital code GONcode.

As exemplified in FIG. 16, the method of compensating the non-idealities of the PGA circuit 410 comprises: receiving calibration data Dcalibr from the data storage circuit 414, the calibration data indicative of the manufacturing process of the SiP comprising the switch Q2; receiving the first digital signal Dvgs from the first ADC circuit 412, the first digital signal Dvgs being indicative of calibration data collected from the manufacturing process of the switch Q2; receiving the second digital signal Dtemp from the second ADC circuit 416, the second digital signal Dtemp being indicative of a temperature of operation of the switch Q2; performing linear interpolation of the received signals Dcalibr, Dtemp, Dvgs, providing as a result a digital conductance value GONcode based on an on-conductance, that is the inverse of the on-resistance Ron, of the switch Q2 at the “real time” operating/driving voltage Vgs and temperature T; and generating a digital control code Acode (e.g, 10 bit digital code) based on the digital conductance value GONcode and varying the direct gain resistances R1, R2 or the inverse gain resistances R1′, R2′ (in a manner per se known) in order to vary the gain of the PGA circuit 410 until it reaches a target value, which may be expressed as PGA_{GAIN}=G_{ON}*5 mV/A.

For instance, the control circuit block 418 may comprise a multiplier circuit and the digital control code Acode may be the result of the multiplication of the digital conductance value GONcode and the first digital signal Dvgs provided by the first ADC circuit 413, thereby mapping the conductance value to control values of the resistive elements R1, R2 of the PGA 410.

As appreciable to those of skill in the art, a conductance Gon equal to an inverse on-resistance Ron of a (e.g., MOSFET) switch Q2 can be expressed as:

$${G}_{ON} = \frac{1}{{R}_{ON}} = \frac{{I}_{D}}{{v}_{DS}} = μ {C}_{ox} \frac{W}{L} ( {V}_{GS} - {V}_{T} )$$

where: VGS is the gate-source operating/driving voltage; VT is the MOSFET threshold voltage; W is the width of the MOSFET channel; L is the length of the MOSFET channel; Cox is the gate oxide capacitance per area unit; and is the mobility parameter of the carriers forming the inversion channel of the MOSFET.

It is advantageous to exploit the linear relation between conductance Gon and temperature T as well as operating voltage Vgs.

FIG. 17 is a diagram exemplary of a linear interpolator circuit 170 which may be used in block 4170 of the digital controller 417 exemplified in FIG. 16.

For the sake of simplicity, one or more embodiments of the interpolator are discussed mainly with reference to an exemplary case of a linear interpolator based on two temperature values, being otherwise understood that such a number of temperature values is purely exemplary and in no way limiting. One or more embodiments may employ an N-temperatures interpolator with N potentially equal to any integer number equal to or greater than two.

As exemplified in FIG. 17, the data storage circuit block 414 comprises at least four data storage cells, for instance: a first data storage cell 4140 configured to store a first manufacturing/assembly process value, e.g., a first conductance value Gon11 at a first operating voltage V1 at a first temperature T1, e.g., G_{ON11}=G_{ON}@V₁, T₁; a second data storage cell 4141 configured to store a second manufacturing process value, e.g., a second conductance value Gon12 at first operating voltage V1 and a second temperature T2, e.g., GON₁₂=G_{ON}@V₁, T₂; a third data storage cell 4142 configured to store a third manufacturing process value, e.g., a third conductance value Gon21 at a second operating voltage V2 and at the first temperature T1, e.g., G_{ON21}=G_{ON}@V₂, T₁; and a fourth data storage cell 4143 configured to store a fourth manufacturing process value, e.g., a fourth conductance value Gon22 at the second operating voltage V2 and at the second temperature T2, e.g., G_{ON22}=G_{ON}@V₂, T₂.

As exemplified in FIG. 17, the linear interpolator 417 comprises: a first multiplexer circuit 4170A coupled to the first 4140 and third 4142 data storage cells of the NVM circuit 414, the first multiplexer circuit 4170A configured to select, based on a selection signal X, one signal Gonx1 among the first Gon11 or third Gon21 process parameters stored in the respective data storage cells 4140, 4142 of the NVM circuit 414; and a second multiplexer circuit 4170B coupled to the second 4141 and fourth 4143 data storage cells of the NVM circuit 414, the second multiplexer circuit 4170B configured to select, based on the selection signal X, one signal Gonx2 among the second Gon12 or fourth Gon22 process parameters stored in the respective data storage cells 4140, 4142 of the NVM circuit 414.

A first linear interpolator circuit 4172 is configured to interpolate a curve between the signals Gonx1, Gonx2 selected by the multiplexers 4170A, 4170B, the interpolated curve being indicative of an evolution over temperatures T1 and T2 of the process parameter Gon of the switch Q2.

As exemplified in FIG. 17, the first linear interpolator circuit 4172 is further configured to receive the digital temperature code Dtemp from the second ADC circuit 416, thereby receiving data related to the real time operating temperature Tj of the switch Q2.

As exemplified, based on the received digital temperature code Dtemp and on each of the interpolated evolution over temperature of the selected process parameters Gonx1, Gonx2 of the switch Q2, the first linear interpolator 4172 is configured to provide a set of estimates Gon1T, Gon2T of the process parameter at the real time temperature Tj and to store them in respective memory cells of a (e.g., RAM) temporary memory circuit 4174. For instance, the set of estimates Gon1T, Gon2T may be sequentially stored in the temporary memory 4174 via a further multiplexer 4173 driven by the selector signal X, where the further multiplexer 4173 selects a respective cell of the RAM 4174 as the respective data value GonxT is provided by the linear interpolator for each value of the selector signal X.

As exemplified in FIG. 17, the linear interpolator 417 further comprises a second linear interpolator 4176 coupled to the temporary memory 4174 to receive the values of process parameters Gon1T, Gon2T at the real time temperature Tj of the switch Q2.

As exemplified in FIG. 17, the second linear interpolator 4176 is configured to: perform a linear interpolation of the data stored in the temporary memory 4174, obtaining as a result a curve indicative of an evolution over operating/driving voltage values Vgs of the process parameter values, and based on the obtained curve, providing 4178 the digital parameter code GONcode as the value GonVT of the process parameter Gon at the real time temperature Tj and real time operating/driving voltage Vgs of the switch Q2 extracted from the obtained curve.

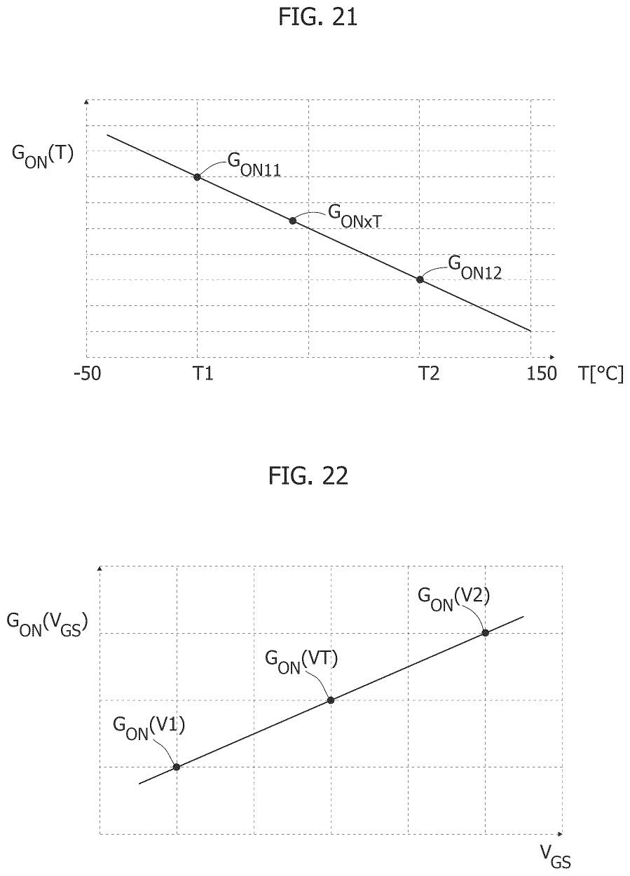

FIG. 21 is a diagram exemplary of an extrapolated curve of the evolution of on-conductance Gon versus temperature T that may be provided by the first linear interpolator circuit block 4172.

FIG. 22 is a diagram exemplary of an extrapolated curve of the evolution of on-conductance Gon versus operating/driving voltage Vgs that may be provided by the second linear interpolator circuit block 4176.

As exemplified in FIGS. 16 and 17, a method comprises measuring 41 a current measurement signal PGAout through a low-side switch Q2 coupled between a switching node SW and a low-side reference node PGND, in which the low-side switch comprises a low-side control terminal configured to receive a low-side control signal as well as a current flow path therethrough between the switching node and the low-side reference node, the low-side switch being configured to be made conductive in response to the low-side control signal having said first logic value during a second time interval, wherein the current flow path through the low-side switch provides a current flow line between the switching node and the low-side reference node.

As exemplified in FIGS. 16 and 17, the method comprises: coupling one input node of a further programmable gain OTA amplifier circuit to said switching node and the other input node of said OTA circuit to said low-side reference node, measuring a voltage drop across the low-side switch; and applying said sensed voltage across a set of variable resistive elements configured to vary the gain of the further OTA circuit, providing said current measurement signal as a result.

For instance, the resistance of at least one variable resistive element in the set of variable resistive elements is set via an error compensating digital code provided via an error compensation circuit.

As exemplified in FIGS. 16 and 17, the error compensation circuit comprises: a Non-Volatile Memory (NVM) circuit having stored thereon parameter values of the low-side switch collected during manufacturing and/or system-in-package assembly thereof at a plurality of temperature and operating voltage values; an operating voltage sensing circuit configured to sense an operating voltage at the control terminal of the low-side switch during measurement of the current measurement signal; a temperature sensing circuit configured to sense an operating temperature of the low-side switch during measurement of the current measurement signal; and a resistance calculation circuit configured to provide said error compensating digital code based on said stored low-side switch parameter values, said sensed operating voltage and said sensed operating temperature.

As exemplified in FIGS. 16 and 17, the process parameters stored on the non-volatile memory comprise a set of on-conductance values of the low-side switch collected by varying an operating temperature for a given operating voltage and by varying the operating voltage at a given operating temperature.

As exemplified in FIGS. 16 and 17, the resistance calculation circuit comprises: a first linear interpolation circuit 4172 configured to perform linear interpolation of sets of said on-conductance values collected at a given operating voltage and stored on the non-volatile memory, providing as a result a set of interpolated curves indicative of an evolution over temperature of the on-conductance of the low-side switch, the first linear interpolator circuit further configured to extract from the set of interpolated curves a set of on-conductance values at the sensed temperature signal; and a second linear interpolation circuit coupled to the first linear interpolator circuit to receive the extracted set of on-conductance values therefrom, the second linear interpolation circuit configured to perform linear interpolation of said extracted on-conductance values, providing as a result an interpolated curve indicative of an evolution over operating voltage of the on-conductance of the low-side switch, the second linear interpolator circuit further configured to extract from the interpolated curve an on-conductance values at the sensed operating voltage.

As exemplified in FIG. 18, the current sensing circuit 40, 40′, 40″ as per the present disclosure may be part of an integrated circuit 180 comprising the half bridge arrangement of switches Q1, Q2, their drivers 220, 221, 222 and other circuitry (per se known) such as bootstrap circuitry 1802, control logic and protection circuitry 1804 and thermal sensing circuitry 1806.

As exemplified in FIG. 19, a plurality of integrated circuits 180 as that exemplified in FIG. 18 may be coupled to a signal processing core, such as a microcontroller unit 190 and to a plurality of respective inductive loads L.

As exemplified in FIG. 20, a plurality of controller units (CU) 190 may be coupled to a plurality of power stages (such as switched converter devices SCD) 180 according to the present disclosure and may be embedded on one or more printed circuit boards (PCBs) 2000 coupled to a battery (B) 10 and equipped on-board a vehicle V, such as an autonomous driving car or electric vehicle.

As exemplified in FIG. 20, the power stages 180 may be used to power loads 301, 302 such as a general purpose processing unit or a data storage unit, known per se.

It will be otherwise understood that the various individual implementing options exemplified throughout the figures accompanying this description are not necessarily intended to be adopted in the same combinations exemplified in the figures. One or more embodiments may thus adopt these (otherwise non-mandatory) options individually and/or in different combinations with respect to the combination exemplified in the accompanying figures.

The claims are an integral part of the technical teaching provided herein with reference to the embodiments.

Without prejudice to the underlying principles, the details and embodiments may vary, even significantly, with respect to what has been described by way of example only, without departing from the extent of protection. The extent of protection is defined by the annexed claims.

1. A method for current sensing in a DCDC converter, wherein the DCDC converter includes: a high-side switch coupled between a high-side reference node and a switching node; a low-side switch coupled between the switching node and a low-side reference node; wherein: the high-side switch comprises a high-side control terminal configured to receive a high-side control signal as well as a current flow path between the high-side reference node and the switching node, the high-side switch being configured to be made conductive in response to the high-side control signal having a first logic value during a first time interval, wherein the current flow path through the high-side switch provides a high-side current flow line between the high-side reference node and the switching node; and the low-side switch comprises a low-side control terminal configured to receive a low-side control signal as well as a current flow path between the switching node and the low-side reference node, the low-side switch being configured to be made conductive in response to the low-side control signal having said first logic value during a second time interval, wherein the current flow path through the low-side switch provides a current flow line between the switching node and the low-side reference node; and an inductive element coupled to the switching node and to an output node configured to be coupled to a load;
the method comprising:
sensing a switching voltage at the switching node;
filtering the sensed switching voltage with a filter circuit to provide a filtered voltage indicative of the output voltage at said output node; and
generating an output current signal, based on a difference between said filtered voltage and said sensed switching voltage, indicative of the intensity of a current flowing through the inductive load during an estimation time equal to or greater than said first time interval.

2. The method of claim 1, wherein said filter circuit comprises a filter circuit having a cut-off frequency based on an expected inductance value of the inductive element.

3. The method of claim 1, further comprising:
receiving, via a measurement circuit, a current measurement signal indicative of a low-side current flowing through said current flow path through said low-side switch; and
applying transconductance amplification with variable gain to the difference of said filtered voltage and said sensed switching voltage to generate an amplified filtered current signal;
wherein the variable gain is based on a digital code set via a digital counter circuit.

4. The method of claim 3, further comprising setting said digital code via said digital counter circuit by:
initiating said digital code of the digital counter to an initial digital code value;
at lapse of said estimation time, comparing said amplified filtered current signal and said current measurement signal;
incrementing or decrementing said digital code based on the comparing of said amplified filtered current signal and said current measurement signal; and
varying the variable gain of said transconductance amplification based on said digital code incremented or decremented via said digital counter.

5. The method of claim 3, wherein the transconductance amplification has an offset current, and the method further comprises:
generating an offset compensating current via a programmable current generator circuit having a programmable current intensity; and
superimposing said offset compensating current to said amplified filtered current signal;
wherein the programmable current intensity of said offset programmable current generator circuit is based on a stored further digital code set via a further digital counter circuit.

6. The method of claim 5, wherein setting said further digital code via said further digital counter circuit comprises:
initiating said digital code of the further digital counter to an initial digital code value equal to zero;
immediately before the start of an estimation time interval, comparing said amplified filtered current signal and said current measurement signal;
decrementing or incrementing said further digital code as a result of said comparing said amplified filtered current signal and said current measurement signal; and
varying the programmable intensity of said offset compensating current generator circuit based on said further digital code incremented or decremented via said further digital counter.

7. The method of claim 3, comprising:
during said estimation time interval, buffering an output of said transconductance amplification to provide the output current signal to user circuits; and
during a remaining time, buffering an output of said measurement circuit to provide the output current signal to user circuits.

8. The method of claim 3, wherein measuring a current measurement signal comprises:
performing a transconductance amplification with a variable gain of a difference between a voltage at said switching node and a voltage at a low side reference node to sense a voltage drop across the low-side switch;
applying said sensed voltage drop to a set of variable resistive elements configured to vary the variable gain of the transconductance amplification to generate said current measurement signal;
setting a resistance of at least one variable resistive element in the set of variable resistive elements using an error compensating digital code provided via an error compensation process;
wherein the error compensation process comprises:
storing in a non-volatile memory circuit parameter values of the low-side switch collected during manufacturing thereof at a plurality of temperature and operating voltage values;
sensing an operating voltage at the control terminal of the low-side switch during measurement of the current measurement signal;
sensing an operating temperature of the low-side switch during measurement of the current measurement signal; and
calculating said error compensating digital code based on said stored low-side switch parameter values, said sensed operating voltage and said sensed operating temperature.

9. The method of claim 8, wherein:
the parameter values stored on the non-volatile memory comprise on-conductance values of the low-side switch collected by varying an operating temperature for a given operating voltage and by varying the operating voltage at a given operating temperature, and
calculating said error compensating digital code comprises:
performing a first linear interpolation of sets of said on-conductance values collected at a given operating voltage and stored on the non-volatile memory to generate a set of interpolated curves indicative of an evolution over temperature of the on-conductance of the low-side switch;
extracting from the set of interpolated curves a set of on-conductance values at the sensed temperature signal;
performing a second linear interpolation on the extracted set of on-conductance values to generate an interpolated curve indicative of an evolution over operating voltage of the on-conductance of the low-side switch;
extracting from the interpolated curve an on-conductance values at the sensed operating voltage.

10. A circuit, comprising:
a high-side switch comprising a high-side control terminal configured to receive a high-side control signal as well as a current flow path between a high-side reference node and a switching node, the high-side switch being configured to be made conductive in response to the high-side control signal having a first logic value during a first time interval, wherein the current flow path through the high-side switch provides a high-side current flow line between the high-side reference node and the switching node;
a low-side switch comprising a low-side control terminal configured to receive a low-side control signal as well as a current flow path between the switching node and a low-side reference node, the low-side switch being configured to be made conductive in response to the low-side control signal having said first logic value during a second time interval, wherein the current flow path through the low-side switch provides a current flow line between the switching node and the low-side reference node;
an inductive element coupled to the switching node and to an output node configured to be coupled to a load;
a filter circuit coupled to said switching node to sense a switching voltage therefrom, the filter circuit configured to provide a filtered voltage based on said sensed switching voltage, the filtered voltage indicative of the output voltage at said output node; and
signal processing circuitry coupled to the filter circuit, the signal processing circuitry configured to, based on a difference between said filtered voltage and said sensed switching voltage, provide to user circuitry an output current signal indicative of the intensity of a current through the inductive load during an estimation time equal to or greater than said first time interval.

11. A switched converter device, comprising:
the circuit according to claim 10;
a battery configured to provide a voltage supply level to said reference node or a ground node configured to provide a ground voltage level to said reference node; and
control circuitry configured to provide said control signal.

12. An electronic control unit, comprising:
at least one switched converter device according to claim 11;
a microcontroller coupled to the at least one switched converter device or to the at least one circuit and configured to provide said control signal thereto; and
at least one load configured to be coupled to the circuit to receive a regulated output voltage therefrom.

13. The electronic control unit according to claim 12, wherein the electronic control unit is mounted onboard a vehicle.

14. A method of measuring a current through a low-side switch coupled between a switching node and a low-side reference node, wherein the low-side switch comprises a low-side control terminal configured to receive a low-side control signal as well as a current flow path between the switching node and the low-side reference node, the low-side switch being configured to be made conductive in response to the low-side control signal having said first logic value during a second time interval, wherein the current flow path through the low-side switch provides a current flow line between the switching node and the low-side reference node, the method comprising:
measuring a voltage drop across the low-side switch by coupling one input node of a programmable gain amplifier circuit to said switching node and the other input node of said programmable gain amplifier circuit to said low-side reference node;
generating a current measurement signal by applying said measured voltage drop across a set of variable resistive elements configured to vary a gain of the programmable gain amplifier circuit,
setting a resistance of at least one variable resistive element in the set of variable resistive elements via an error compensating digital code generated by an error compensation process;
the error compensation process comprises:
storing a non-volatile memory circuit parameter values of the low-side switch collected during manufacturing thereof at a plurality of temperature and operating voltage values;
sensing an operating voltage at the control terminal of the low-side switch during measurement of the current measurement signal;
sensing an operating temperature of the low-side switch during measurement of the current measurement signal, and
calculating resistance to provide said error compensating digital code based on said stored low-side switch parameter values, said sensed operating voltage and said sensed operating temperature.

15. The method of claim 14, wherein:
collecting on-conductance values of the low-side switch as the parameter values stored on the non-volatile memory by varying an operating temperature for a given operating voltage and by varying the operating voltage at a given operating temperature; and
calculating resistance comprises:
performing a first linear interpolation of sets of said on-conductance values collected at a given operating voltage and stored on the non-volatile memory to generate a set of interpolated curves indicative of an evolution over temperature of the on-conductance of the low-side switch;
extracting from the set of interpolated curves a set of on-conductance values at the sensed temperature signal;
performing a second linear interpolation of said extracted on-conductance values to generate an interpolated curve indicative of an evolution over operating voltage of the on-conductance of the low-side switch; and
extracting from the interpolated curve an on-conductance values at the sensed operating voltage.
